(19) United States
(12) Patent Application Publication
(10) Pub. No.: US 2024/0392218 A1
(43) Pub. Date: Nov. 28, 2024

(54) CLEANING LIQUID, METHOD OF CLEANING SUBSTRATE, AND METHOD OF MANUFACTURING SEMICONDUCTOR ELEMENT

(71) Applicant: TOKYO OHKA KOGYO CO., LTD., Kawasaki-shi (JP)

(72) Inventors: Kohei SERIZAWA, Kawasaki-shi (JP); Emi UCHIDA, Kawasaki-shi (JP)

(21) Appl. No.: 18/659,895

(22) Filed: May 9, 2024

(30) Foreign Application Priority Data
May 25, 2023 (JP) 2023-086305

(51) Int. Cl. C11D 7/32; C11D 7/26; C11D 7/50; H01L 21/02; H01L 21/033; H01L 21/311

(52) U.S. Cl. CPC C11D 7/3209; C11D 7/265; C11D 7/5004; H01L 21/0206; H01L 21/0332; H01L 21/0337; C11D 2111/22; H01L 21/31116

(57) ABSTRACT

A cleaning liquid for removing an etching residue containing a titanium component, the cleaning liquid including a compound represented by General Formula (a1) below, in which the cleaning liquid has a pH of 6 or greater, which is measured at 23° C., in which R represents an organic group or a hydrogen atom

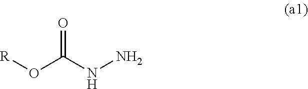

### BACKGROUND OF THE INVENTION

### Field of the Invention

The present invention relates to a cleaning liquid, a method of cleaning a substrate, and a method of manufacturing a semiconductor element.

Priority is claimed on Japanese Patent Application No. 2023-086305, filed on May 25, 2023, the content of which is incorporated herein by reference.

### Description of Related Art

In the wiring forming step, for example, a hard mask layer (HM layer) is formed on an interlayer insulating film in which a substrate, a metal wiring layer, and a silicon-based interlayer insulating film are laminated in this order, and the HM layer is etched to form an original form of a wiring pattern. The HM layer contains a titanium component such as titanium nitride (TiN) or titanium oxide (TiOx).

Next, the interlayer insulating film is dry-etched using the etched HM layer as a mask to prepare a wiring pattern similar to that of the mask. Next, the HM layer is removed, and for example, a copper metal film is embedded into the interlayer insulating film having a wiring pattern shape by electroplating.

Inorganic substance-containing residues derived from the metal wiring layer, organic substance-containing residues derived from the interlayer insulating film or the etching gas, and titanium component-containing residues derived from the HM layer are adhered to the dry-etched element (the substrate/the metal wiring layer/the interlayer insulating film/the HM layer).

Dry etching residues are removed by a cleaning treatment in the related art.

A cleaning liquid containing hydroxylamine and alkanolamine as a residue removing agent has been suggested as a cleaning liquid for removing dry etching residues (see, for example, Patent Document 1).

### CITATION LIST

### Patent Document

Patent Document 1—Japanese Unexamined Patent Application, First Publication No. H4-289866

### SUMMARY OF THE INVENTION

### Technical Problem

The titanium component-containing residues derived from the HM layer adhering to the dry-etched element are residues having high wet resistance and difficult to remove by a cleaning treatment.

In a case where the cleaning liquid described in Patent Document 1 is used, the cleaning liquid is effective for removing the titanium component-containing residues, but an alternative to the residue removing agent is desired from the viewpoint of the safety of hydroxylamine.

The present invention has been made in consideration of the above-described circumstances, and an object thereof is to provide a cleaning liquid in which removal properties of titanium component-containing residues adhering to a dry-etched element are satisfactory and the safety is enhanced, and a method of cleaning a substrate and a method of manufacturing a semiconductor element, using this cleaning liquid.

### Solution to Problem

In order to solve the above problem, the present invention has adopted the following configuration.

According to a first aspect of the present invention, there is provided a cleaning liquid for removing an etching residue containing a titanium component, the cleaning liquid including: a compound (A) represented by General Formula (a1), in which the cleaning liquid has a pH of 6 or greater, which is measured at 23° C.

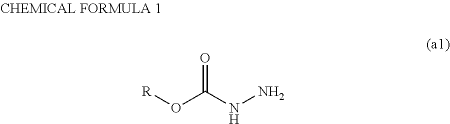

In the formula, R represents an organic group or a hydrogen atom.

According to a second aspect of the present invention, there is provided a method of cleaning a substrate, including: a step (P1) of cleaning a substrate to which an etching residue containing a titanium component is adhered, using the cleaning liquid according to the first aspect.

According to a third aspect of the present invention, there is provided a method of manufacturing a semiconductor element, including: a step (P1) of cleaning a substrate to which an etching residue containing a titanium component is adhered, using the cleaning liquid according to the first aspect.

### Advantageous Effects of Invention

According to the present invention, it is possible to provide a cleaning liquid in which removal properties of titanium component-containing residues adhering to a dry-etched element are satisfactory and the safety is enhanced, and a method of cleaning a substrate and a method of manufacturing a semiconductor element, using this cleaning liquid.

### BRIEF DESCRIPTION OF THE DRAWING

FIG. 1 is a cross-sectional view showing an example of a dry-etched element which is a cleaning target.

### DETAILED DESCRIPTION OF THE INVENTION

### First Aspect: Cleaning Liquid

A cleaning liquid according to a first aspect of the present invention is a cleaning liquid for removing an etching residue containing a titanium component.

The term “titanium component” here is a compound containing titanium (Ti), and examples thereof include titanium oxide TiOx, titanium nitride TiNx, titanium chloride TiClx, and titanium fluoride TiFx.

The etching residue is particularly a dry etching residue, and examples thereof include a titanium component-containing residue derived from a titanium component-containing layer (such as an adhesive layer, a hard mask layer, or an etching stop layer) that adheres by performing a wiring process. The dry etching residue degrades the yield and electrical characteristics of a semiconductor, and thus is required to be removed before the next step.

The cleaning liquid according to the present aspect is suitable for cleaning a substrate that has been subjected to dry etching, and particularly suitable for cleaning a substrate that has been subjected to dry etching using a titanium component-containing hard mask by a wiring process.

In the cleaning liquid according to the present aspect, “substrate that has been subjected to dry etching”, which is a cleaning target, includes a titanium component-containing layer and the concept thereof includes a single substrate and an element provided with a substrate.

A cleaning liquid according to an embodiment in the present aspect is a cleaning liquid containing a compound (A) represented by General Formula (a1) and a solvent, in which the cleaning liquid has a pH of 6 or greater, which is measured at 23° C.

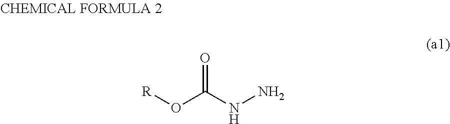

In the formula, R represents an organic group or a hydrogen atom.

### Compound (A)

The cleaning liquid according to the present embodiment contains a compound (A) (hereinafter, also referred to as “component (A)”) represented by General Formula (a1). In the cleaning liquid, the component (A) is used as a residue removing agent. An effect of removing titanium component-containing residues of the cleaning liquid can be increased by using the component (A) as the residue removing agent. In addition, the component (A) has higher safety than that of hydroxylamine used for general purposes in the related art as a residue removing agent.

Examples of the organic group as R in Formula (a1) include a hydrocarbon group which may have a substituent. The hydrocarbon group may be an aliphatic hydrocarbon group or an aromatic hydrocarbon group, but is preferably an aliphatic hydrocarbon group.

The number of carbon atoms of the aliphatic hydrocarbon group as R is preferably in a range of 1 to 10, more preferably in a range of 1 to 6, and still more preferably in a range of 1 to 4.

The aliphatic hydrocarbon group as R may be a saturated aliphatic hydrocarbon group or an unsaturated aliphatic hydrocarbon group, but is preferably a saturated aliphatic hydrocarbon group.

The aliphatic hydrocarbon group as R may be chain-like or cyclic, but is preferably chain-like.

Among these, a linear or branched chain alkyl group is preferable as the aliphatic hydrocarbon group as R.

The linear alkyl group as R is preferably an alkyl group having 1 to 6 carbon atoms, more preferably an alkyl group having 1 to 3 carbon atoms, still more preferably a methyl group or an ethyl group, and particularly preferably a methyl group. The branched chain alkyl group as R has preferably 3 or 4 carbon atoms and more preferably 4 carbon atoms.

R represents preferably a linear or branched chain alkyl group having 1 to 6 carbon atoms or a hydrogen atom, more preferably a linear or branched chain alkyl group having 1 to 4 carbon atoms or a hydrogen atom, and still more preferably a methyl group, an ethyl group, a tert-butyl group, or a hydrogen atom.

Specific examples of the component (A) are shown below.

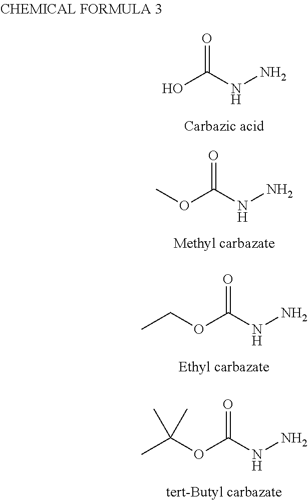

In the cleaning liquid according to the present embodiment, the component (A) may be used alone or in combination of two or more kinds thereof.

In a case where the cleaning liquid contains two or more kinds of the components (A), the content ratio of each component is not limited, but the ratio of the content of other kinds of the components (A) to the content of one kind of the component (A) is preferably in a range of 1 to 10,000, more preferably in a range of 1 to 5,000, still more preferably in a range of 1 to 3,000, and particularly preferably in a range of 1 to 1,000, in terms of the mass ratio.

Among examples, the component (A) is preferably at least one selected from the group consisting of a carbazic acid alkyl ester and carbazic acid, more preferably at least one selected from the group consisting of methyl carbazate, ethyl carbazate, tert-butyl carbazate, and carbazic acid, and still more preferably at least one selected from the group consisting of methyl carbazate and carbazic acid.

The content of the component (A) in the cleaning liquid of the present embodiment is not particularly limited, but is preferably 0.01% by mass or greater and 30% by mass or less, more preferably 0.05% by mass or greater and 30% by mass or less, and still more preferably 0.5% by mass or greater and 30% by mass or less with respect to the total mass of the cleaning liquid.

In a case where the content of the component (A) is greater than or equal to the lower limits of the above-described preferable ranges, the removal properties of the titanium component-containing residues after dry etching in the cleaning treatment are further enhanced. Meanwhile, in a case where the content of the component (A) is less than or equal to the upper limits of the above-described preferable ranges, damage to the metal wiring is further suppressed.

### Solvent

It is preferable that the cleaning liquid of the present embodiment contains water as a solvent.

Water may contain a trace amount of components that are unavoidably mixed. As water that may be used in the cleaning liquid of the present embodiment, water subjected to a purification treatment, such as distilled water, ion exchange water, or ultrapure water is preferable, and ultrapure water typically used in the manufacture of a semiconductor is more preferable.

Water can be blended into the cleaning liquid according to the present embodiment in an amount such that the total content of the component (A), the following optional components blended as necessary, and water becomes 100% by mass, that is, the content of water is the remaining amount.

The cleaning liquid according to the present embodiment may contain an organic solvent described below as a solvent in addition to water, or may use water and an organic solvent in combination.

### Optional Components

The cleaning liquid according to the present embodiment may contain optional components in addition to the component (A) and the solvent. Examples of the optional components include a base, a carboxylic acid (excluding components corresponding to the compound (A)), an anticorrosive agent, a buffer, an organic solvent, a surfactant, and a pH adjusting agent.

### Base

It is preferable that the cleaning liquid according to the present embodiment further contains a base in addition to the component (A). In a case where the cleaning liquid contains a base, the pH of the cleaning liquid can be adjusted to be high, and thus the effect of removing the titanium component-containing residues of the component (A) is likely to be exhibited.

Examples of the base include those selected from the group consisting of amines and ammonium compounds.

Examples of the amine as the base include ammonia (NH₃), a primary monoamine, a secondary monoamine, a tertiary monoamine, alkanolamine, a secondary cyclic amine, a tertiary cyclic amine, a quaternary cyclic amine, a diamine, a polyamine.

Examples of the primary monoamine include alkylamines such as methylamine, ethylamine, propylamine, n-butylamine, isopropylamine, and tert-butylamine; cycloalkylamines such as cyclopentylamine, cyclohexylamine, and cyclohexanemethylamine; and alkoxyamines such as methoxyethylamine, methoxypropylamine, methoxybutylamine, ethoxypropylamine, and propoxypropylamine.

Examples of the secondary monoamine include alkylamines such as dimethylamine, diethylamine, methylethylamine, dipropylamine, diisopropylamine, dibutylamine, diisobutylamine, and butylmethylamine; cycloalkylamines such as N,N-dicyclohexylamine and N-cyclopentylcyclohexanamine; and alkoxyamines such as methoxy(methylamine) and N-(2-methoxyethyl)ethylamine.

Examples of the tertiary monoamine include alkylamines such as trimethylamine, triethylamine, tripropylamine, tributylamine, triisobutylamine, dimethylethylamine, dimethylpropylamine, allyldiethylamine, dimethyl-n-butylamine, and diethylisopropylamine; and cycloalkylamines such as tricyclopentylamine and tricyclohexylamine.

Examples of the alkanolamine include monoethanolamine, 2-aminoethanol, 1-amino-2-propanol, 2-amino-1-propanol, 4-amino-1-butanol, 2-amino-2-methyl-1-propanol, 2-(2-aminoethoxy)ethanol, N-methylethanolamine, N-ethylethanolamine, N-methylpropanolamine, 2-diethanolamine, diisopropanolamine, [(hydroxymethyl)amino]ethanol, 4-methylaminobutanol, 3-piperidinemethanol, 4-piperidinemethanol, 2-piperidineethanol, 4-piperidineethanol, N,N-dimethylethanolamine, N,N-dimethylpropanolamine, N,N-diethylethanolamine, N-ethyldiethanolamine, N-methyldiethanolamine, triethanolamine, and triisopropanolamine.

Examples of the secondary cyclic amines include piperidines (compounds having a piperidine skeleton), pyrrolidines (compounds having a pyrrolidine skeleton), and morpholines (compounds having a morpholine skeleton). Examples of the piperidines which are secondary cyclic amines include piperidine, 2-pipecoline, 3-pipecoline, 4-pipecoline, 2,6-dimethylpiperidine, and 3,5-dimethylpiperidine. Examples of the pyrrolidines include pyrrolidine, 2-methylpyrrolidine, and 3-methylpyrrolidine. Examples of the morpholines include morpholine, 2-methylmorpholine, and 3-methylmorpholine.

Examples of the tertiary cyclic amines include piperidines, pyrrolidines, and morpholines. Examples of the piperidines include N-methylpiperidine. Examples of the pyrrolidines include N-methylpyrrolidine. Examples of the morpholines include N-methylmorpholine.

Examples of the quaternary cyclic amines include fluorides, chlorides, bromides, iodides, sulfates, hydrogensulfates, and acetates of piperidines, pyrrolidines, and morpholines.

The diamine may be any of a primary diamine, a secondary diamine, or a tertiary diamine. Examples of the primary diamine include 2-(2-aminoethylamino)ethanol, ethylenediamine, butane-1,4-diamine, 1,3-propanediamine, 1,6-hexanediamine, and pentane-1,5-diamine. Examples of the secondary diamine include 2-methylpiperazine, 2,3-dimethylpiperazine, 2,5-dimethylpiperazine, N,N′-dimethylethanediamine, N,N′-dimethylpropanediamine, N,N′-diethylethylenediamine, N,N′-diethylpropanediamine, and N,N′-diisopropylethylenediamine. Examples of the tertiary diamine include 4-dimethylaminopyridine, N,N,N′,N′-tetramethylethylenediamine, N,N,N′,N′-tetraethylethylenediamine, N,N,N′,N′-tetramethyl-1,3-diaminopropane, N,N,N′,N′-tetramethyl-1,3-diaminobutane, N′,N′-tetramethyl-1,4-diaminobutane, N,N,N′,N′-tetramethylphenylenediamine, and 1,2-dipiperidinoethane.

The polyamine is a compound containing three or more amino groups, and a triamine is preferable. The polyamine may contain any of a primary amino group, a secondary amino group, or a tertiary amino group. Examples of the polyamine include spermine, spermidine, 3,3′-iminobis(propylamine), N,N-bis(3-aminopropyl)methylamine, N,N-bis(3-aminopropyl)butylamine, N-(3-aminopropyl)-N-dodecylpropane-1,3-diamine, diethylenetriamine, N,N,N′,N″,N″-pentamethyldiethylenetriamine, N,N,N′,N″,N″-pentamethyldipropylenetriamine, tris[2-(dimethylamino)ethyl]amine, 2-aminomethylpyrimidine, 1,4-bis(3-aminopropyl)piperazine, 1-amino-4-cyclopentylpiperazine, and 1-(2-pyridyl)piperazine.

Examples of the ammonium compound as the base include a hydroxide of a quaternary amine and a quaternary ammonium salt other than a hydroxide.

Tetraalkylammonium hydroxide is preferable as the hydroxide of a quaternary amine, and examples thereof include tetramethylammonium hydroxide, tetraethylammonium hydroxide, tetrapropylammonium hydroxide, dimethylbis(2-hydroxyethyl) ammonium hydroxide, tetrabutylammonium hydroxide, tetrapentylammonium hydroxide, tris(2-hydroxyethyl)methylammonium hydroxide, choline, dimethyldiethylammonium hydroxide, tetraethanolammonium hydroxide, benzyltrimethylammonium hydroxide, benzyltriethylammonium hydroxide, and benzyltributylammonium hydroxide.

Examples of the quaternary ammonium salt other than the hydroxide include a fluoride, a chloride, a bromide, an iodide, a sulfate, a hydrogensulfate, and an acetate of quaternary ammonium. Specific examples of the quaternary ammonium salt include tetraethylammonium chloride, tetramethylammonium chloride, tetrapropylammonium chloride, tetrabutylammonium chloride, tetrapentylammonium chloride, tetraethylammonium bromide, tetramethylammonium bromide, tetrapropylammonium bromide, tetrabutylammonium bromide, tetrapentylammonium bromide, tetraethylammonium fluoride, tetramethylammonium fluoride, tetrapropylammonium fluoride, tetrabutylammonium fluoride, tetrapentylammonium fluoride, tetraethylammonium iodide, tetramethylammonium iodide, tetrapropylammonium iodide, tetrabutylammonium iodide, tetrapentylammonium iodide, tetraethylammonium hydrogensulfate, tetramethylammonium hydrogensulfate, tetrapropylammonium hydrogensulfate, and tetrabutylammonium hydrogensulfate.

In the cleaning liquid according to the present embodiment, the base may be used alone or in combination of two or more kinds thereof.

Among the bases, it is preferable to use at least one selected from the group consisting of ammonia, alkanolamine, tetraalkylammonium hydroxide, a triamine, and a diamine and more preferable to use at least one selected from the group consisting of ammonia, monoethanolamine, tetraethylammonium hydroxide, diethylenetriamine, and 2-(2-aminoethylamino)ethanol.

Among these, from the viewpoint of the removal properties of the titanium component-containing residues, it is preferable to use, as the base, at least one selected from the group consisting of ammonia, tetraalkylammonium hydroxide, and alkanolamine and more preferable to use at least one selected from the group consisting of ammonia and tetraalkylammonium hydroxide.

The base in the cleaning liquid according to the present embodiment can be blended within a range where the pH of the cleaning liquid which is measured at 23° C. is adjusted to 6 or greater.

For example, the content of the base in the cleaning liquid according to the present embodiment may be 0.01% by mass or greater and 30% by mass or less, 0.05% by mass or greater and 20% by mass or less, or 0.5% by mass or greater and 15% by mass or less with respect to the total mass of the cleaning liquid.

In a case where the content of the base is greater than or equal to the lower limits of the above-described ranges, the removal properties of the titanium component-containing residues in the cleaning treatment are further enhanced. Meanwhile, in a case where the content of the base is less than or equal to the upper limits of the above-described ranges, the effect of combining the base with the component (A) is likely to be obtained.

### Carboxylic Acid (Excluding Components Corresponding to Compound (A))

The cleaning liquid according to the present embodiment may further contain a carboxylic acid (excluding components corresponding to the compound (A)) in addition to the component (A) and the base. In a case where the carboxylic acid is used in combination, the pH can be easily adjusted due to an increase in the buffering capacity of the composition of the cleaning liquid, and the temporal stability of the cleaning liquid is improved.

Examples of the carboxylic acid here include those selected from the group consisting of a dicarboxylic acid, a hydroxy acid, a fatty acid, and an amino acid.

Examples of the dicarboxylic acid include aliphatic dicarboxylic acids such as oxalic acid, malonic acid, succinic acid, glutaric acid, adipic acid, pimelic acid, suberic acid, azelaic acid, sebacic acid, maleic acid, fumaric acid, and itaconic acid; aromatic dicarboxylic acids such as phthalic acid, isophthalic acid, and terephthalic acid; and N-(2-acetamido)iminodiacetic acid (ADA). Here, the dicarboxylic acid excludes components corresponding to the hydroxy acid.

Examples of the hydroxy acid include glycolic acid, lactic acid, tartaric acid, citric acid, malic acid, hydroxybutyric acid, taltronic acid, glyceric acid, citramalic acid, isocitric acid, leucic acid, mevalonic acid, pantoic acid, ricinoleic acid, ricinelaidic acid, cerebronic acid, quinic acid, shikimic acid, gluconic acid, and diglycolic acid.

Examples of the fatty acid include fatty acids having 1 to 22 carbon atoms, and examples thereof include formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, eicosapentaenoic acid, and docosahexaenoic acid.

Examples of the amino acid include glycine, alanine, arginine, asparagine, aspartic acid, cysteine, glutamine, glutamic acid, histidine, isoleucine, leucine, lysine, methionine, phenylalanine, proline, serine, threonine, tryptophan, tyrosine, and valine.

In the cleaning liquid according to the present embodiment, the carboxylic acid may be used alone or in combination of two or more kinds thereof.

Among the carboxylic acids, it is preferable to use at least one selected from the group consisting of a dicarboxylic acid, a hydroxy acid, a fatty acid, and an amino acid and more preferable to use at least one selected from the group consisting of oxalic acid, lactic acid, tartaric acid, citric acid, acetic acid, and glycine.

Among these, from the viewpoint of the removal properties of the titanium component-containing residues, it is preferable to use at least one selected from the group consisting of oxalic acid, lactic acid, and acetic acid and more preferable to use oxalic acid and lactic acid as the carboxylic acid.

In a case where the cleaning liquid according to the present embodiment contains a carboxylic acid, the content of the carboxylic acid in the cleaning liquid may be 0.01% by mass or greater and 30% by mass or less, 0.05% by mass or greater and 20% by mass, or 0.5% by mass or greater and 15% by mass or less with respect to the total mass of the cleaning liquid.

In a case where the content of the carboxylic acid is greater than or equal to the lower limits of the above-described ranges, the buffering capacity of the composition in the cleaning liquid is likely to increase. Meanwhile, in a case where the content of the carboxylic acid is less than or equal to the upper limits of the above-described ranges, the effect of combining the carboxylic acid with the base is likely to be obtained.

### Anticorrosive Agent

The cleaning liquid of the present embodiment may contain an anticorrosive agent.

Examples of the anticorrosive agent include compounds having a nitrogen-containing heterocyclic ring such as a triazole ring, an imidazole ring, a pyridine ring, a phenanthroline ring, a tetrazole ring, a pyrazole ring, a pyrimidine ring, or a purine ring.

### Buffer

The cleaning liquid according to the present embodiment may contain a buffer. The buffer is a compound having an action of suppressing a change in the pH of a cleaning liquid.

The buffer is not particularly limited as long as the buffer is a compound having a pH buffering capacity. As the buffer, for example, a compound with a pKa of 6 to 11 can be used.

Examples of the buffer include a Good's buffer. Example of the Good's buffer include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl)methane (Bis-Tris), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl)piperazine-1-(2-hydroxypropane-3-sulfonic acid) (HEPSO), and 4-(2-hydroxyethyl)-1-piperazinepropanesulfonic acid (EPPS).

The cleaning liquid of the present embodiment may not contain the buffer, and may not contain one or more of the compounds exemplified as specific examples of the buffer.

### Organic Solvent

The cleaning liquid according to the present embodiment may contain an organic solvent. The organic solvent is preferably a water-soluble organic solvent. In a case where the cleaning liquid contains an organic solvent, organic residues such as polymers are easily removed. Examples of the water-soluble organic solvent include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, 2-methyl-2,4-pentanediol, and 3-methoxy-3-methyl-1-butanol; dimethyl sulfoxide; ethers such as ethylene glycol dimethyl ether, diethylene glycol dimethyl ether, triethylene glycol dimethyl ether, tetraethylene glycol dimethyl ether, and propylene glycol dimethyl ether; and morpholines such as N-methylmorpholine N-oxide.

The organic solvent may be used alone or in combination of two or more kinds thereof.

Among the organic solvents, it is preferable to use at least one selected from the group consisting of alcohols, ethers, and morpholines, more preferable to use at least one selected from the group consisting of alcohols, and still more preferable to use 2-methyl-2,4-pentanediol.

In a case where the cleaning liquid according to the present embodiment contains an organic solvent, the content of the organic solvent is preferably in a range of 0.05% to 90% by mass, more preferably in a range of 0.1% to 75% by mass, still more preferably in a range 0.1% to 50% by mass, and particularly preferably in a range of 0.1% to 25% by mass with respect to the total mass of the cleaning liquid.

The cleaning liquid according to the present embodiment may not contain the organic solvent or the water-soluble organic solvent, and may not contain one or more of the compounds described as specific examples of the water-soluble organic solvent.

In a case where a mixed solvent of water and an organic solvent is used as the solvent of the cleaning liquid, the content of the organic solvent is preferably in a range of 10% to 90% by mass, more preferably in a range of 20% to 80% by mass, and still more preferably in a range of 25% to 75% by mass with respect to the total mass of the cleaning liquid.

### Surfactant

The cleaning liquid of the present embodiment may contain a surfactant, for example, for the purpose of adjusting the wettability of the cleaning liquid to a substrate. Examples of the surfactant include a nonionic surfactant, an anionic surfactant, a cationic surfactant, and an amphoteric surfactant.

Examples of the nonionic surfactant include polyalkylene oxide alkylphenyl ether-based surfactants, polyalkylene oxide alkyl ether-based surfactants, block polymer-based surfactants consisting of polyethylene oxide and polypropylene oxide, polyoxyalkylene distyrenated phenyl ether-based surfactants, polyalkylene tribenzylphenyl ether-based surfactants, and acetylene polyalkylene oxide-based surfactants.

Examples of the anionic surfactant include alkylsulfonic acids, alkylbenzenesulfonic acids, alkylnaphthalenesulfonic acids, alkyldiphenyl ether sulfonic acids, fatty acid amidosulfonic acids, polyoxyethylene alkyl ether carboxylic acids, polyoxyethylene alkyl ether acetic acids, polyoxyethylene alkyl ether propionic acids, alkyl phosphonic acids, and fatty acid salts. Examples of “salts” include ammonium salts, sodium salts, potassium salts, and tetramethylammonium salts.

Examples of cationic surfactant include alkylpyridium-based surfactants and quaternary ammonium salt-based surfactants.

Examples of the amphoteric surfactant include betaine type surfactants, amino acid type surfactants, imidazoline type surfactants, and amine oxide type surfactants.

These surfactants are generally commercially available. The surfactant may be used alone or in combination of two or more kinds thereof.

In a case where the cleaning liquid of the present embodiment contains the surfactant, the content of the surfactant is not particularly limited, but is, for example, preferably in a range of 0.0001% by mass to 5% by mass, more preferably in a range of 0.0002% by mass to 3% by mass, still more preferably in a range of 0.002% by mass to 1% by mass, and particularly preferably in a range of 0.002% by mass to 0.2% by mass with respect to the total mass of the cleaning liquid.

The cleaning liquid according to the present embodiment may not contain one or more selected from the group consisting of a nonionic surfactant, an anionic surfactant, a cationic surfactant, and an amphoteric surfactant, and may not contain one or more of the compounds described as the surfactant. The cleaning liquid of the present embodiment may not contain the surfactant.

### pH Adjusting Agent

A pH adjusting agent other than the base and the carboxylic acid described above may be used in the cleaning liquid according to the present embodiment in order to adjust the pH to a desired value. Examples of the pH adjusting agent include inorganic acids and organic acids.

### Impurities and the Like

The cleaning liquid of the present embodiment may include metal impurities including metal atoms such as a Fe atom, a Cr atom, an Ni atom, a Zn atom, a Ca atom, and a Pb atom.

The total content of the metal atoms in the cleaning liquid of the present embodiment is preferably 100 ppt by mass or less with respect to the total mass of the cleaning liquid. The lower limit of the total content of the metal atoms is preferably as low as possible, but may be, for example, 0.001 ppt by mass or greater. The total content of the metal atoms may be, for example, 0.001 ppt by mass to 100 ppt by mass. By setting the total content of the metal atoms to less than or equal to the preferable upper limit, the defect suppressing properties and the residue suppressing properties of the cleaning liquid are improved. It is considered that in a case where the total content of the metal atoms is set to greater than or equal to the preferable lower limit, the metal atoms are less likely to be released in the system and less likely to adversely affect the production yield of the entire object to be cleaned.

The content of the metal impurities can be adjusted, for example, by a purification treatment such as filtering. A purification treatment such as filtering may be performed on a part or all of the raw materials before preparing the cleaning liquid, or may be performed after preparing the cleaning liquid.

The cleaning liquid of the present embodiment may include, for example, organic substance-derived impurities (organic impurities). The total content of the organic impurities in the cleaning liquid of the present embodiment is preferably 5,000 ppm by mass or less. The lower limit of the content of the organic impurities is preferably as low as possible, and the lower limit may be, for example, greater than or equal to 0.1 ppm by mass. The total content of the organic impurities is, for example, 0.1 ppm by mass to 5,000 ppm by mass.

The cleaning liquid of the present embodiment may include, for example, objects to be counted having a size that can be counted by a light scattering type in-liquid particle counter. The size of the object to be counted is, for example, 0.04 μm or greater. The number of the objects to be counted in the cleaning liquid of the present embodiment is, for example, 1,000 or less per mL of the cleaning liquid, and the lower limit is, for example, 1 or greater. It is considered that in a case where the number of the objects to be counted in the cleaning liquid is within the range, the metal corrosion suppressing effect of the cleaning liquid is improved.

The organic impurities and/or the objects to be counted may be added to the cleaning liquid, or may be unavoidably mixed in the cleaning liquid during a step of producing the cleaning liquid. Examples of the cases where organic impurities are unavoidably mixed in the step of producing the cleaning liquid include a case where raw materials (for example, an organic solvent) used in the production of the cleaning liquid contain organic impurities and a case where organic impurities are mixed (for example, contamination) from the external environment in the step of producing the cleaning liquid.

In a case where the objects to be counted are added to the cleaning liquid, the existence ratio may be adjusted for each specific size in consideration of the surface roughness and the like of a cleaning target.

### pH of Cleaning Liquid

The pH of the cleaning liquid according to the present embodiment, which is measured at 23° C., is 6 or greater, preferably in a range of 7 to 13, more preferably in a range of 8 to 12.5, still more preferably in a range of 9 to 12.5, and particularly preferably in a range of 10 to 12.

In a case where the pH of the cleaning liquid is greater than or equal to the lower limits of the above-described ranges, the removal properties of the titanium component-containing residues after dry etching is enhanced in the cleaning treatment.

The pH of the cleaning liquid is a value measured at 23° C. with a pH meter under a condition of a normal pressure (1 atm).

Suitable examples of the cleaning liquid according to the present embodiment include the following embodiments (1-1) and (1-2).
Embodiment (1-1): A cleaning liquid containing a compound (A) represented by General Formula (a1), a base, and water, in which the pH measured at 23° C. is 6 or greater.
Embodiment (1-2): A cleaning liquid containing a compound (A) represented by General Formula (a1), a base, a carboxylic acid (excluding components corresponding to the compound (A)), and water, in which the pH measured at 23° C. is 6 or greater.

### In Regard to Embodiment (1-1):

The cleaning liquid according to the embodiment (1-1) contains a compound (A), a base, and water as the remaining amount, and may contain optional components as necessary.

It is preferable to use at least one selected from the group consisting of methyl carbazate, ethyl carbazate, tert-butyl carbazate, and carbazic acid as the compound (A).

It is preferable to use at least one selected from the group consisting of ammonia, alkanolamine, tetraalkylammonium hydroxide, a triamine, and a diamine and more preferable to use ammonia or tetraalkylammonium hydroxide as the base.

It is preferable to use only water or a mixed solvent of water and an organic solvent as the solvent.

The pH of the cleaning liquid according to the embodiment (1-1), which is measured at 23° C., is 6 or greater, preferably in a range of 10 to 13, and more preferably in a range of 11 to 12.

The content of the compound (A) in the cleaning liquid according to the embodiment (1-1) is preferably 0.01% by mass or greater and 30% by mass or less, more preferably 0.5% by mass or greater and 20% by mass or less, still more preferably 1% by mass or greater and 10% by mass or less, and particularly preferably 2.5% by mass or greater and 7% by mass or less with respect to the total mass of the cleaning liquid.

### In Regard to Embodiment (1-2):

The cleaning liquid according to the embodiment (1-2) contains a compound (A), a base, a carboxylic acid (excluding components corresponding to the compound (A)), and water as the remaining amount, and may contain optional components as necessary.

It is preferable to use at least one selected from the group consisting of methyl carbazate, ethyl carbazate, tert-butyl carbazate, and carbazic acid, more preferable to use at least one selected from the group consisting of methyl carbazate and carbazic acid, and still more preferable to use at least methyl carbazate as the compound (A).

It is preferable to use at least one selected from the group consisting of ammonia, alkanolamine, tetraalkylammonium hydroxide, a triamine, and a diamine, more preferable to use at least one selected from the group consisting of ammonia, monoethanolamine, tetraethylammonium hydroxide, diethylenetriamine, and 2-(2-aminoethylamino)ethanol, still more preferable to use at least one selected from the group consisting of ammonia, tetramethylammonium hydroxide, tetraethylammonium hydroxide, and monoethanolamine, and particularly preferable to use at least one selected from the group consisting of ammonia, tetramethylammonium hydroxide, and tetraethylammonium hydroxide as the base.

It is preferable to use at least one selected from the group consisting of a dicarboxylic acid, a hydroxy acid, a fatty acid, and an amino acid, more preferable to use at least one selected from the group consisting of oxalic acid, lactic acid, tartaric acid, citric acid, acetic acid, and glycine, still more preferable to use at least one selected from the group consisting of oxalic acid, lactic acid, and acetic acid, and particularly preferable to use oxalic acid or lactic acid as the carboxylic acid.

It is preferable to use only water or a mixed solvent of water and an organic solvent as the solvent.

The content of the compound (A) in the cleaning liquid according to the embodiment (1-2) is preferably 0.01% by mass or greater and 30% by mass or less, more preferably 0.05% by mass or greater and 30% by mass or less, and still more preferably 0.5% by mass or greater and 30% by mass or less with respect to the total mass of the cleaning liquid.

The pH of the cleaning liquid according to the embodiment (1-2), which is measured at 23° C., is 6 or greater, preferably in a range of 7 to 13, more preferably in a range of 8 to 12.5, still more preferably in a range of 9 to 12.5, and particularly preferably in a range of 10 to 12.

A method of storing the cleaning liquid of the present embodiment is not particularly limited, and storage containers known in the related art can be used. In order to ensure the stability of the cleaning liquid, a void ratio in a container in a case of storing the cleaning liquid in the container and/or a type of gas filling the voids may be appropriately set. For example, the void ratio in the storage container may be approximately in a range of 0.01% to 30% by volume.

As described above, the cleaning liquid according to the present embodiment contains the compound (A) represented by General Formula (a1), and the pH thereof, which is measured at 23° C., is 6 or greater. According to the cleaning liquid, the removal properties of the titanium component-containing residues adhering to a dry-etched element are satisfactory.

In the compound (A), the compound (A) is carbazic acid in a case where R in General Formula (a1) represents a hydrogen atom. In a case where R in General Formula (a1) represents an organic group, since the pH of the cleaning liquid is 6 or greater, carbazic acid can be generated by the hydrolysis of the compound (A), which is an ester, during the cleaning. The effect of the cleaning liquid according to the present embodiment is assumed to be exhibited because the carbazic acid actively acts for removing the titanium component-containing residues.

In addition, since the compound (A) is employed as a residue removing agent in the cleaning liquid according to the present embodiment, the safety of the cleaning liquid is further enhanced as compared with hydroxylamine used for general purposes in the related art.

### Second Aspect: Method of Cleaning Substrate

A method of cleaning a substrate according to a second aspect of the present invention includes a step (P1) of cleaning a substrate to which etching residues containing a titanium component are adhered, using the cleaning liquid according to the first aspect.

In the cleaning method according to the present aspect, the concept of the substrate to which etching residues (titanium component-containing residues), serving as a cleaning target, containing a titanium component are adhered includes a single substrate and an element provided with a substrate.

The element may be an element after a metal wiring layer is subjected to dry etching by, for example, a semi-damascene process. Further, the element may be an element in which a metal wiring layer is exposed after a Si-containing layer (for example, a Si-containing interlayer insulating film) is subjected to dry etching by a wiring process. Further, the element may be a substrate in which a metal wiring layer is exposed after a CMP step in a wiring process.

Suitable examples of the metal wiring layer include a layer containing at least one metal selected from the group consisting of molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, and thallium.

Hereinafter, an embodiment of the method of cleaning a substrate according to the present aspect will be described with reference to the accompanying drawing.

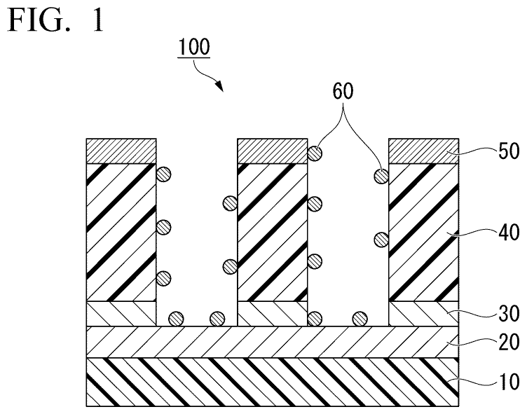

FIG. 1 shows an example of a dry-etched element (the substrate/the metal wiring layer/the interlayer insulating film/the HM layer) as an element including a substrate which is a cleaning target.

An element 100 shown in FIG. 1 is formed such that a substrate 10, a metal wiring layer 20, an etching stop layer 30, and an interlayer insulating film 40 are laminated in this order and a hard mask layer (HM layer) 50 is formed on the interlayer insulating film 40.

The element 100 is an element that has been subjected to dry etching by the wiring process, that is, an element in a state after the interlayer insulating film 40 is dry-etched using the HM layer 50 on which an original form of a wiring pattern has been formed by dry etching, as a mask. Dry etching residues 60 adhere to the side surfaces of the HM layer 50 and the interlayer insulating film 40.

In space portions between the interlayer insulating films 40 having a wiring pattern shape, the metal wiring layer 20 is exposed, and the dry etching residues 60 are also adhered to the exposed metal wiring layer 20.

The substrate 10 is formed of a material such as silicon, amorphous silicon, or glass.

The metal wiring layer 20 is a wiring layer formed of metals such as molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium., vanadium, gallium, hafnium, indium, niobium, rhenium, and thallium.

The interlayer insulating film 40 is formed of a silicon-based material such as SiO₂, SiN, SiOC, SiOF, SiOCH, SiCN, SiOF, or SiOH.

The HM layer 50 is a titanium component-containing layer formed of a titanium component such as titanium nitride (TiN) or titanium oxide (TiOx).

The dry etching residues 60 are mainly titanium component-containing residues containing a titanium component derived from the HM layer 50.

### Cleaning Step (P1)

The present step (P1) is a step of cleaning the element 100 after the element is dry-etched by the wiring process using the cleaning liquid according to the first aspect.

The cleaning method is not particularly limited, and a known cleaning method can be used.

In a case where the cleaning liquid is brought into contact with the element 100 which is a cleaning target, the cleaning liquid may be diluted 2 to 2,000 times to obtain a diluted liquid, and an operation of cleaning the element 100 using the diluted liquid may be performed.

Examples of the cleaning operation include a method of continuously coating the element 100 rotating at a constant speed with the cleaning liquid (rotation coating method), a method of dipping the element 100 in the cleaning liquid for a certain time (dip method), and a method of spraying the cleaning liquid to the surface of the element 100 (spraying method).

The temperature at which the cleaning treatment is performed is not particularly limited. The cleaning treatment is performed under a temperature condition of preferably 10° C. to 80° C., and the temperature may be in a range of 20° C. to 75° C. or 40° C. to 70° C.

The removal properties of the etching residues are improved by increasing the temperature of the cleaning liquid, but the temperature of the cleaning liquid can be appropriately selected in consideration of suppression of a change in the composition of the cleaning liquid, workability, the safety, the cost, and the like.

As the cleaning time, a time sufficient for removing etching residues, impurities, and the like adhering to the surface of the element 100 can be appropriately selected. The washing time is, for example, in a range of 10 seconds to 30 minutes, and may be in a range of 20 seconds to 15 minutes, in a range of 30 seconds to 10 minutes, or in a range of 30 seconds to 5 minutes.

According to the cleaning method of the present embodiment described above, since the element 100 to which the dry etching residues 60 are adhered is cleaned by using the cleaning liquid according to the first aspect, the titanium component-containing residues derived from the HM layer 50 can be satisfactorily cleaned and removed while damage to the metal wiring layer 20 is suppressed. Further, according to the cleaning method of the present embodiment, damage to the interlayer insulating film 40 can also be suppressed.

In addition, since the compound (A) is employed as a residue removing agent in the cleaning liquid, a semiconductor element and the like can be more safely manufactured as compared with hydroxylamine used for general purposes in the related art.

In the method of cleaning a substrate according to the embodiment described above, the case where the HM layer 50 in FIG. 1 is a titanium component-containing layer has been described, but the method of cleaning a substrate according to the second aspect of the present invention is not limited to the embodiment, and for example, the etching stop layer 30 may be a titanium component-containing layer or an adhesive layer (not shown) formed by bonding each layer constituting the element 100 may be a titanium component-containing layer. That is, the method of cleaning a substrate according to the present aspect is a method particularly useful in a case where a substrate serving as a cleaning target is a substrate that includes a titanium component-containing layer and has been subjected to dry etching.

### (Third Aspect: Method of Manufacturing Semiconductor Element)

A method of manufacturing a semiconductor element according to a third aspect of the present invention is a manufacturing method including a step (P1) of cleaning a substrate to which etching residues including a titanium component are adhered, using the cleaning liquid according to the first aspect.

A manufacturing method including the step (P1) and optional steps is an exemplary example of an embodiment of the method of manufacturing a semiconductor element.

In the manufacturing method according to the present embodiment, the step (P1) can be performed in the same manner as the method described in the section of [cleaning step (P1)] of (second aspect: method of cleaning substrate) described above.

Examples of the optional steps include a hard mask layer etching step, a wiring layer dry-etching step, and a contact etching step, before the step (P1). Further, examples of the optional steps include known steps performed in a case of manufacturing a semiconductor element, such as formation steps (such as layer formation, etching other than the above-described etching treatment, chemical-mechanical polishing, transformation) of capacitor formation, channel formation, High-K/metal gate formation, each structure such as a metal wiring, a gate structure, a source structure, a drain structure, an insulating layer, a ferromagnetic layer, or a nonmagnetic layer, a resist film forming step, a light exposure step, a development step, a heat treatment step, and an inspection step.

Since the method of manufacturing a semiconductor element of the present embodiment described above includes a step (P1) of cleaning a substrate to which etching residues (titanium component-containing residues) including a titanium component are adhered, using the cleaning liquid according to the first aspect, the etching residues can be satisfactorily removed while damage to the metal wiring is suppressed. In this manner, the electrical characteristics of a semiconductor element to be manufactured can be improved.

### EXAMPLES

Hereinafter, the present invention will be described in more detail based on examples, but the present invention is not limited to these examples.

Components used in examples and comparative examples are shown below.

### Residue Removing Agent

(A)-1: hydroxylamine
(A)-2: carbazic acid
(A)-3: methyl carbazate
(A)-4: ethyl carbazate
(A)-5: tert-butyl carbazate

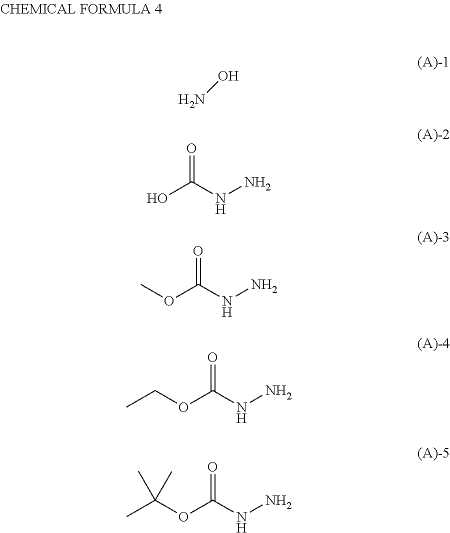

### Base

(B)-1: monoethanolamine
(B)-2: triethanolamine.
(B)-3: ammonia
(B)-4: tetraethylammonium hydroxide
(B)-5: diethylenetriamine
(B)-6:2-(2-aminoethylamino)ethanol
(B)-7: tetramethylammonium hydroxide

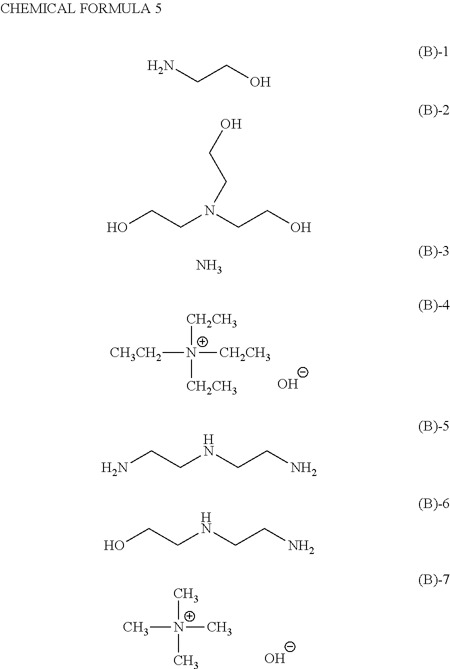

### Carboxylic Acid

(C)-1: gluconic acid
(C)-2: oxalic acid
(C)-3: lactic acid
(C)-4: tartaric acid
(C)-5: citric acid.
(C)-6: acetic acid
(C)-7: glycine

### Solvent

(S)-1: water
(S)-2:2-methyl-2,4-pentanediol

### Preparation of Cleaning Liquid

### Comparative Examples 1 to 4 and Examples 1 to 31

Each component listed in Tables 1 and 2 was used to prepare a cleaning liquid of each example.

In Tables 1 and 2, each abbreviation has the meaning described above. The numerical values in the brackets denote the content of each component in the cleaning liquid, and indicate the proportion (% by mass) of the content mass of each component in the total mass (100% by mass in total) of the cleaning liquid.

In the cleaning liquid of each example, the pH of the cleaning liquid which was measured at 23° C. was adjusted to the value listed in the table by adjusting the content of the base.

### pH of Cleaning Liquid

The pH of the cleaning liquid was measured using a pH meter (portable pH meter D-73S, manufactured by Horiba, Ltd.) under a temperature condition of 23° C. The results are listed in Tables 1 and 2 in the columns of “pH (23° C.)”.

### Evaluation

In the cleaning liquids of each example, the removal properties of titanium component-containing residues after being subjected to dry etching were evaluated using the etching rates described below as an index.

### Measurement of Etching Rate

A substrate obtained by forming a titanium nitride (TiN) film having a film thickness of 50 nm on a 12-inch silicon substrate using a PVD method was used as the substrate.

The substrate on which the film had been formed was cut into a size of 2 cm×2 cm to produce a wafer coupon.

100 mL of the cleaning liquid of each example was put into a beaker having a volume of 200 mL and heated to a treatment temperature of 60° C., and the cut wafer coupon was dipped in the cleaning liquid. The temperature of the cleaning liquid was continuously increased to 60° C. while the wafer coupon was dipped in the cleaning liquid. The wafer coupon was taken out from the cleaning liquid 3 hours after the dipping, cleaned with water at room temperature for 30 seconds, and dried by blowing nitrogen.

The film thicknesses of the wafer coupon before and after the dipping in the cleaning liquid were measured.

The film thicknesses of the wafer coupon including a TiN film were measured using an X-ray fluorescence spectrometer (ZSX Primus IV, Rigaku Corporation).

Further, the etching rate was calculated from the change in the film thickness of the TiN film before and after the cleaning treatment.

### Evaluation of Removal Properties of Titanium Component-Containing Residues

The removal properties of the titanium component-containing residues were evaluated according to the following evaluation criteria using the etching rates of the cleaning liquid with respect to the TIN film as an index. The results are listed in Tables 1 and 2.

The removal properties of the titanium component-containing residues are more excellent as the value of the etching rate increases.

### Evaluation Criteria of Removal Properties of Titanium Component-Containing Residues

A: The etching rate of the cleaning liquid with respect to the TiN film was greater than 0.5×10⁻¹⁰ m/min.
B: The etching rate thereof was greater than 0.25×10⁻¹⁰ m/min and 0.5×10⁻¹⁰ m/min or less.
C: The etching rate thereof was greater than 0.15×10⁻¹⁰ m/min and 0.25×10⁻¹⁰ m/min or less.
D: The etching rate thereof was 0.15×10⁻¹⁰ m/min or less.

TABLE 1

| | Composition of cleaning liquid/mass % | | | | | | |
|---|---|---|---|---|---|---|---|
| | Residue | | | | | Treatment | Removal properties of |
| | removing | | Carboxylic | | pH | temperature | titanium component- |
| | agent | Base | acid | Solvent | (23° C.) | [° C.] | containing residue |
| Comparative | (A)-1 | — | — | (S)- | 9.8 | 60 | A |
| Example 1 | [1.0] | | | [remaining amount] | | | |
| Comparative | — | (B)-1 | (C)-1 | (S)- | 11.7 | 60 | D |
| Example 2 | | [48.5] | [22] | [remaining amount] | | | |
| | | (B)-2 | | | | | |
| | | [22] | | | | | |
| Comparative | (A)-3 | (B)-3 | (C)-2 | (S)-1 | 3.0 | 60 | D |
| Example 3 | [4.5] | | [6.3] | [remaining amount] | | | |
| Comparative | (A)-3 | (B)-3 | (C)-2 | (S)-1 | 5.0 | 60 | D |
| Example 4 | [4.5] | | [6.3] | [remaining amount] | | | |
| Example 1 | (A)-2 | (B)-3 | — | (S)-1 | 11.1 | 60 | A |
| | [4.0] | | | [remaining amount] | | | |
| Example 2 | (A)-3 | (B)-3 | — | (S)-1 | 11.8 | 60 | A |
| | [4.5] | | | [remaining amount] | | | |
| Example 3 | (A)-5 | (B)-3 | — | (S)-1 | 11.7 | 60 | A |
| | [6.6] | | | [remaining amount] | | | |
| Example 4 | (A)-4 | (B)-3 | — | (S)-1 | 11.8 | 60 | A |
| | [4.5] | | | [remaining amount] | | | |
| Example 5 | (A)-2 | (B)-3 | — | (S)-1 | 11.7 | 60 | A |
| | [2.0] | | | [remaining amount] | | | |
| | (A)-3 | | | | | | |
| | [2.5] | | | | | | |
| Example 6 | (A)-3 | (B)-3 | (C)-2 | (S)-1 | 10.0 | 60 | A |
| | [4.5] | | [6.3] | [remaining amount] | | | |
| Example 7 | (A)-3 | (B)-3 | (C)-3 | (S)-1 | 10.0 | 60 | A |
| | [4.5] | | [4.5] | [remaining amount] | | | |
| Example 8 | (A)-3 | (B)-3 | (C)-4 | (S)-1 | 10.0 | 60 | B |
| | [4.5] | | [7.5] | [remaining amount] | | | |
| Example 9 | (A)-3 | (B)-3 | (C)-5 | (S)-1 | 10.0 | 60 | B |
| | [4.5] | | [9.6] | [remaining amount] | | | |
| Example 10 | (A)-3 | (B)-3 | (C)-6 | (S)-1 | 10.0 | 60 | A |
| | [4.5] | | [3.0] | [remaining amount] | | | |
| Example 11 | (A)-3 | (B)-3 | (C)-7 | (S)-1 | 10.0 | 60 | B |
| | [4.5] | | [3.8] | [remaining amount] | | | |

TABLE 2

| | Composition of cleaning liquid/mass % | | | | | | Removal properties |
|---|---|---|---|---|---|---|---|
| | Residue | | | | | Treatment | of titanium |
| | removing | | Carboxylic | | pH | temperature | component- |
| | agent | Base | acid | Solvent | (23° C.) | [° C.] | containing residue |
| Example 12 | (A)-3 | (B)-1 | (C)-2 | (S)-1 | 10.0 | 60 | A |
| | [4.5] | | [6.3] | [remaining amount] | | | |
| Example 13 | (A)-3 | (B)-4 | (C)-3 | (S)-1 | 10.0 | 60 | A |
| | [4.5] | | [4.0] | [remaining amount] | | | |
| Example 14 | (A)-3 | (B)-7 | (C)-3 | (S)-1 | 10.0 | 60 | A |
| | [4.5] | | [4.0] | [remaining amount] | | | |
| Example 15 | (A)-3 | (B)-4 | (C)-2 | (S)-1 | 13.0 | 60 | B |
| | [4.5] | | [6.3] | [remaining amount] | | | |
| Example 16 | (A)-3 | (B)-5 | (C)-2 | (S)-1 | 10.0 | 60 | B |
| | [4.5] | | [6.3] | [remaining amount] | | | |
| Example 17 | (A)-3 | (B)-6 | (C)-2 | (S)-1 | 10.0 | 60 | B |
| | [4.5] | | [6.3] | [remaining amount] | | | |
| Example 18 | (A)-3 | (B)-4 | (C)-2 | (S)-1 | 14.0 | 60 | C |
| | [4.5] | | [6.3] | [remaining amount] | | | |
| Example 19 | (A)-3 | (B)-3 | (C)-2 | (S)-1 | 12.0 | 60 | A |
| | [4.5] | | [6.3] | [remaining amount] | | | |
| Example 20 | (A)-3 | (B)-3 | (C)-2 | (S)-1 | 8.0 | 60 | B |
| | [4.5] | | [6.3] | [remaining amount] | | | |
| Example 21 | (A)-3 | (B)-3 | (C)-2 | (S)-1 | 7.0 | 60 | B |
| | [4.5] | | [6.3] | [remaining amount] | | | |
| Example 22 | (A)-3 | (B)-3 | (C)-2 | (S)-1 | 6.0 | 60 | C |
| | [4.5] | | [6.3] | [remaining amount] | | | |
| Example 23 | (A)-3 | (B)-3 | (C)-2 | (S)-1 | 10.0 | 60 | A |
| | [30] | | [6.3] | [remaining amount] | | | |
| Example 24 | (A)-3 | (B)-3 | (C)-2 | (S)-1 | 10.0 | 60 | A |
| | [10] | | [6.3] | [remaining amount] | | | |
| Example 25 | (A)-3 | (B)-3 | (C)-2 | (S)-1 | 10.0 | 60 | A |
| | [1.0] | | [6.3] | [remaining amount] | | | |
| Example 26 | (A)-3 | (B)-3 | (C)-2 | (S)-1 | 10.0 | 60 | A |
| | [0.5] | | [6.3] | [remaining amount] | | | |
| Example 27 | (A)-3 | (B)-3 | (C)-2 | (S)-1 | 10.0 | 60 | B |
| | [0.05] | | [6.3] | [remaining amount] | | | |
| Example 28 | (A)-3 | (B)-3 | (C)-2 | (S)-1 | 10.0 | 60 | C |
| | [0.01] | | [6.3] | [remaining amount] | | | |
| Example 29 | (A)-3 | (B)-4 | (C)-3 | (S)-2 | 10.0 | 60 | A |
| | [4.5] | | [4.0] | [75] | | | |
| | | | | (S)-1 | | | |
| | | | | [remaining amount] | | | |
| Example 30 | (A)-3 | (B)-4 | (C)-3 | (S)-2 | 10.0 | 60 | A |
| | [4.5] | | [4.0] | [50] | | | |
| | | | | (S)-1 | | | |
| | | | | [remaining amount] | | | |
| Example 31 | (A)-3 | (B)-4 | (C)-3 | (S)-2 | 10.0 | 60 | A |
| | [4.5] | | [4.0] | [25] | | | |
| | | | | (S)-1 | | | |
| | | | | [remaining amount] | | | |

As shown the results listed in Tables 1 and 2, it was confirmed that the cleaning liquids of Examples 1 to 31 to which the present invention was applied had satisfactory removal properties of the titanium component-containing residues as compared with the cleaning liquids of Comparative Examples 2 to 4 which were outside the scope of the present invention.

In addition, in the cleaning liquids of Examples 1 to 31, the residue removing agent was replaced with the compound (A), and thus the safety was enhanced.

Hereinbefore, the preferable examples of the present invention have been described, but the present invention is not limited thereto. Additions, omissions, substitutions, and other modifications can be made without departing from the scope of the present invention. The present invention is not limited by the above description, but only by the appended claims.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

10: Substrate
20: Metal wiring layer
30: Etching stop layer
40: Interlayer insulating film
50: Hard mask layer (HM layer)
60: Dry etching residue
100: Element

What is claimed is:

1. A cleaning liquid for removing an etching residue containing a titanium component, the cleaning liquid comprising:
a compound (A) represented by General Formula (a1),
wherein the cleaning liquid has a pH of 6 or greater which is measured at 23° C., 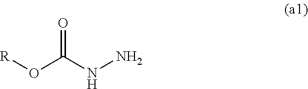
wherein R represents an organic group or a hydrogen atom.

2. The cleaning liquid according to claim 1, wherein the cleaning liquid has a pH of 7 to 13, which is measured at 23° C.

3. The cleaning liquid according to claim 1, further comprising a base.

4. The cleaning liquid according to claim 1, further comprising an organic solvent.

5. The cleaning liquid according to claim 3, wherein the base is at least one selected from the group consisting of ammonia, alkanolamine, tetraalkylammonium hydroxide, a triamine, and a diamine.

6. The cleaning liquid according to claim 1, wherein a content of the compound (A) is in a range of 0.01% to 30% by mass with respect to a total mass of the cleaning liquid.

7. The cleaning liquid according to claim 3, further comprising a carboxylic acid, and excluding a component corresponding to the compound (A).

8. The cleaning liquid according to claim 7, wherein the carboxylic acid is at least one selected from the group consisting of a dicarboxylic acid, a hydroxy acid, a fatty acid, and an amino acid.

9. The cleaning liquid according to claim 8, wherein the carboxylic acid is at least one selected from the group consisting of oxalic acid, lactic acid, tartaric acid, citric acid, acetic acid, and glycine.

10. The cleaning liquid according to claim 1, wherein the cleaning liquid is used for cleaning a substrate that includes a titanium component-containing layer and has been subjected to dry etching.

11. The cleaning liquid according to claim 10, wherein the cleaning liquid is used for cleaning the substrate that has been subjected to dry etching using a titanium component-containing hard mask by a wiring process.

12. A method of cleaning a substrate, comprising cleaning a substrate to which an etching residue including a titanium component is adhered, using the cleaning liquid according to claim 1.

13. The method of cleaning a substrate according to claim 12, wherein the cleaning the substrate is performed using the cleaning liquid at 10° C. to 80° C.

14. The method of cleaning a substrate according to claim 12, wherein the substrate includes a titanium component-containing layer and has been subjected to dry etching.

15. The method of cleaning a substrate according to claim 14, wherein the substrate has been subjected to dry etching using a titanium component-containing hard mask by a wiring process.

16. A method of manufacturing a semiconductor element, the method comprising cleaning a substrate to which an etching residue including a titanium component is adhered, using the cleaning liquid according to claim 1.
